(19) United States
(12) Patent Application Publication
(10) Pub. No.: US 2024/0206119 A1
(43) Pub. Date: Jun. 20, 2024

(54) VAPOR CHAMBER

(71) Applicant: COOLER MASTER CO., LTD., Taipei City (TW)

(72) Inventors: Hua-Yuan LIN, Taipei City (TW); Lei Lei LIU, Hui Zhou City (CN); Yao-Chun WANG, Taipei City (TW)

(73) Assignee: COOLER MASTER CO., LTD., Taipei City (TW)

(21) Appl. No.: 18/543,812

(22) Filed: Dec. 18, 2023

(30) Foreign Application Priority Data
Dec. 19, 2022 (CN) 202211633409.8

(51) Int. Cl. H05K 7/20

(52) U.S. Cl. CPC H05K 7/20336

(57) ABSTRACT

A vapor chamber including a first plate, second plate, plurality of first support structures, plurality of second support structures, and at least one tubular heat transfer structure is provided. The first plate and the second plate define an interior cavity having a first, second, and third portion, the first, second, and third portion each have a first, second, and third depth, respectively, the plurality of first support structures is disposed in the first portion, the plurality of support structures is disposed in the second portion and the third portion, respectively, the at least one tubular heat transfer structure is disposed in the first portion and includes a first working fluid having a first working fluid circulation path, the first portion, the second portion, and the third portion include a second working fluid having a second working fluid circulation path different from the first working fluid circulation path.

### RELATED APPLICATIONS

This US application claims the benefit of priority to China application No. 202211633409.8, filed on Dec. 19, 2022, of which is incorporated herein by reference in its entirety.

### TECHNICAL FIELD

The present disclosure is related to the field of heat transfer in general and more particularly but not limited to vapor chambers.

### BACKGROUND

With the increase of the processing speed and performance of electronic components, such as application-specific integrated circuits (ASICs) and central processing units (CPU), the amount of heat generated during the operation of the electronic component increases. The heat generation increases the temperature of the electronic component and, if the heat cannot be dissipated effectively, the reliability and performance of the electronic component are reduced.

To prevent overheating of an electronic component of a thin and compact electronic device, a vapor chamber may be used. The generated heat of the electronic component is conducted through a limited area of the electronic component to a larger area of the vapor chamber, and the generated heat can be unevenly and inefficiently distributed along the vapor chamber. Consequently, the vapor chamber may not adequately cool the electronic component, potentially causing the electronic component to overheat.

### SUMMARY

Aspects of the disclosure provide a vapor chamber. The vapor chamber includes a first plate, a second plate opposite the first plate, the first plate and the second plate defining an interior cavity. The interior cavity can include a first portion, a second portion, and a third portion, the first portion surrounded by the second portion at a perimeter edge of the first portion, the second portion surrounded by the third portion at a perimeter edge of the second portion, the first portion having a first depth extending from the first plate to the second plate, the second portion having a second depth extending from the first plate to the second plate, and the third portion having a third depth extending from the first plate to the second plate, a plurality of first support structures disposed in the first portion, each plurality of first support structures having a first ends and a second end opposite to each other, the first ends of the first support structures contact the second plate, a plurality of support structures disposed in the second portion and the third portion, respectively, each plurality of support structures having an end and a second end opposite to each other, the first ends of the second support structures contact the second plate, and the second ends of the second support structures contact the first plate, and at least one tubular heat transfer structure disposed in the first portion, the at least one tubular heat transfer structure extending from the first plate to the second plate and including a first working fluid having a first working fluid circulation path, wherein the first depth is greater than the second depth and the second depth is greater than the third depth, and wherein the first portion, the second portion, and the third portion include a second working fluid having a second working fluid circulation path different from the first working fluid circulation path.

In an embodiment, the vapor chamber can further include a plurality of heat transfer base structures, the plurality of heat transfer base structures disposed in the first portion, each plurality of heat transfer base structures having a first heat transfer base contact end and a second heat transfer base contact end opposite to each other, the second heat transfer base contact ends contact the first plate, the first heat transfer base contact ends contact the first ends of the first support structures.

In some embodiments, the interior cavity can further include a first surface area defined by a second plate surface area of the first portion, a second surface area defined by a second plate surface area of the second portion, and a third surface area defined by a second plate surface area of the third portion, wherein the first surface area, the second surface area, and the third surface area are configured so that a gas phase of the second working fluid condenses back into a liquid phase when cooled.

In some embodiments, the interior cavity can further include a plurality of first liquid flow surfaces defined by a first plate surface area of the first portion and surface areas of each of the plurality of support structures and surface areas of each of the plurality of heat transfer base structures disposed in the first portion, a plurality of second liquid flow surfaces defined by a first plate surface area of the second portion and surface areas of each of the plurality of support structures disposed in the second portion, and a plurality of third liquid flow surfaces defined by a first plate surface area of the third portion and surface areas of each of the plurality of support structures disposed in the third portion, wherein the plurality of first liquid flow surfaces, the plurality of second liquid flow surfaces, and the plurality of third liquid flow surfaces are configured so that the second working fluid that is condensed back into a liquid phase when cooled flows to an outer tubular liquid flow surface of the at least one tubular heat transfer structure.

For example, the vapor chamber can further include a capillary structure, the capillary structure is disposed on the plurality of first liquid flow surfaces, the plurality of second liquid flow surfaces, and the plurality of third liquid flow surfaces.

For example, the vapor chamber can further include an outer tubular capillary structure, the outer tubular capillary structure is disposed on the outer tubular liquid flow surface.

For example, the first plate surface area is further configured so that the first working fluid transitions between a liquid phase and a gas phase when heated.

For example, the second working fluid circulation path is defined from the outer tubular liquid flow surface of the at least one tubular heat transfer structure, to at least one of the first surface area, the second surface area, and the third surface area, and then back through at least one of the plurality of first liquid flow surfaces, the plurality of second liquid flow surfaces, or the plurality of third liquid flow surfaces, to the outer tubular liquid flow surface.

For example, the outer tubular liquid flow surface is configured so that the second working fluid that is condensed back into a liquid phase when cooled flows to the first plate surface area, and wherein the at least one tubular heat transfer structure further includes a first tubular surface area, a second tubular surface area, and an inner tubular liquid flow surface, the first tubular surface area defined by a first plate surface area of the at least one tubular heat transfer structure, and the second tubular surface defined by a second plate surface area of the at least one tubular heat transfer structure, wherein the first tubular surface area is configured so that the first working fluid transitions between a liquid phase and a gas phase when heated, the second tubular surface area is configured so that the first working fluid condenses back into a liquid phase when cooled, and the inner tubular liquid flow surface is configured so that the first working fluid that is condensed back into a liquid phase when cooled flows to the first tubular surface area, and wherein the first working fluid circulation path is defined from the first tubular surface area, to the second tubular surface area, and then back through the inner tubular liquid flow surface, to the first tubular surface area.

In an embodiment, the vapor chamber can further include an inner tubular capillary structure, the inner tubular capillary structure is disposed on the inner tubular liquid flow surface.

In an embodiment, the vapor chamber can further include a shape of the plurality of first support structures comprise a cuboid shape, and wherein a shape of the plurality of support structures include a cylinder shape.

In an embodiment, the vapor chamber can further include a shape of the plurality of heat transfer base structures include at least one of an elongated oval-like shape, an elongated barbell-like shape, or a wavy bump shape.

In an embodiment, the vapor chamber can further include a heat source contact surface opposite the first portion, the heat source contact surface configured to thermally couple to a heat source, whereby the at least one tubular heat transfer structure decreases a vapor space of the first portion, increasing a temperature within the first portion, and increasing a temperature difference between the temperature within the first portion and the temperature within the second portion and the third portion when the heat source contact surface is thermally coupled to the heat source.

In an embodiment, the at least two of the plurality of first support structures is disposed on each of the plurality of heat transfer base structures.

In some embodiments, the vapor chamber can further include a first heat pipe having a first pipe body and a pipe capillary structure, the pipe capillary structure disposed in the first pipe body, and wherein the second plate includes at least one through hole and at least one flange, each of the at least one flange extending from each of the at least one through hole, respectively, wherein the at least one through hole is disposed through the first surface area, and whereby the first heat pipe is received in the at least one through hole and the at least one tubular heat transfer structure, and the at least one flange and the at least one tubular heat transfer structure surround the first heat pipe, and wherein the first working fluid circulation path is defined from the first tubular surface area, to an upper portion of the first pipe body, and then back through the pipe capillary structure, to the first tubular surface area.

In an embodiment, the vapor chamber can further include a plurality of heat pipes, each, including a pipe body, wherein, each of the plurality of heat pipes is received in the at least one through hole, and the at least one flange surrounds each of the plurality of heat pipes, respectively, and wherein the at least one through hole is disposed through at least one of the second surface area and the third surface area, wherein the second working fluid circulation path is defined from the outer tubular capillary structure of the at least one tubular heat transfer structure, to at least one of the first surface area, the second surface area and each of an upper portion of the plurality of heat pipes, and the third surface area and each of an upper portion of the plurality of heat pipes, and then back through at least one of the plurality of first liquid flow surfaces, the pipe body and the plurality of second liquid flow surfaces, and the pipe body and the plurality of third liquid flow surfaces, to the outer tubular liquid flow surface.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of vapor chambers incorporating aspects of the presently disclosed principles are illustrated by way of example, and not by way of limitation.

FIG. 1A illustrates a perspective view of a vapor chamber 100 according to one embodiment of the present disclosure.

FIG. 1B illustrates an exploded view of the vapor chamber 100 according to one embodiment of the present disclosure.

FIG. 2 illustrates a perspective view of a first plate of the vapor chamber 100 according to one embodiment of the present disclosure.

FIG. 3 illustrates a cross-sectional view of the vapor chamber 100 according to one embodiment of the present disclosure.

FIG. 4 illustrates a cross-sectional view of an alternative vapor chamber 100A according to one embodiment of the present disclosure.

FIG. 5A illustrates a perspective view of an alternative vapor chamber 100B according to one embodiment of the present disclosure.

FIG. 5B illustrates an exploded view of the alternative vapor chamber 100B according to one embodiment of the present disclosure.

FIG. 6 illustrates a partial cross-sectional view of the alternative vapor chamber 100B according to one embodiment of the present disclosure.

FIG. 7 illustrates a process S100 for manufacturing of a vapor chamber according to one embodiment of the present disclosure.

### DETAILED DESCRIPTION

The following describes various principles related to thermal control of electronic components by way of reference to specific examples of vapor chambers, including specific arrangements and examples of interior cavity portions embodying innovative concepts. More particularly, but not exclusively, such innovative principles are described in relation to selected examples of plurality of heat transfer structures disposed in the interior cavity and how the plurality of heat transfer structures decrease a vapor space to evenly and efficiently distribute heat along the vapor chamber, increase a velocity of flow of working fluid that is condensed back into a liquid phase to a center of the vapor chamber, and allow the flow of working fluid to the center of the vapor chamber to travel unhindered, and well-known functions or constructions are not described in detail for purposes of succinctness and clarity. Nonetheless, one or more of the disclosed principles can be incorporated in various other embodiments of a plurality of heat transfer structures to achieve any of a variety of desired outcomes, characteristics, and/or performance criteria.

Thus, vapor chambers having attributes that are different from those specific examples discussed herein can embody one or more of the innovative principles, and can be used in applications not described herein in detail. Accordingly, embodiments of vapor chambers not described herein in detail also fall within the scope of this disclosure, as will be appreciated by those of ordinary skill in the relevant art following a review of this disclosure.

Example embodiments as disclosed herein are directed to vapor chambers, wherein a surface of the vapor chamber is thermally coupled to an electronic component, transporting heat away therefrom, and to working fluid inside of the vapor chamber. In response to receiving the heat, a portion of the working fluid transitions from a liquid phase to a gas phase. The gas portion of the working fluid rises and distributes the received heat substantially evenly along the second plate of the vapor chamber. The second plate transfers the heat to ambient air outside of the vapor chamber. The working fluid condenses back into a liquid in response to conducting the heat to the second plate and the liquid returns to a center of the vapor chamber where the cycle is repeated.

The vapor chambers may be configured within an electric or electronics system that includes heat producing electronic components to be cooled.

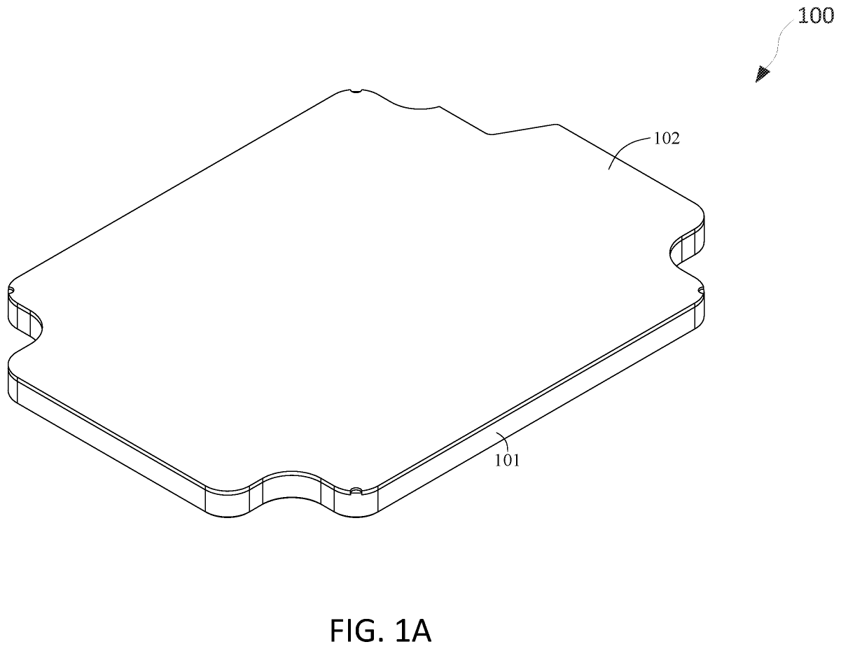

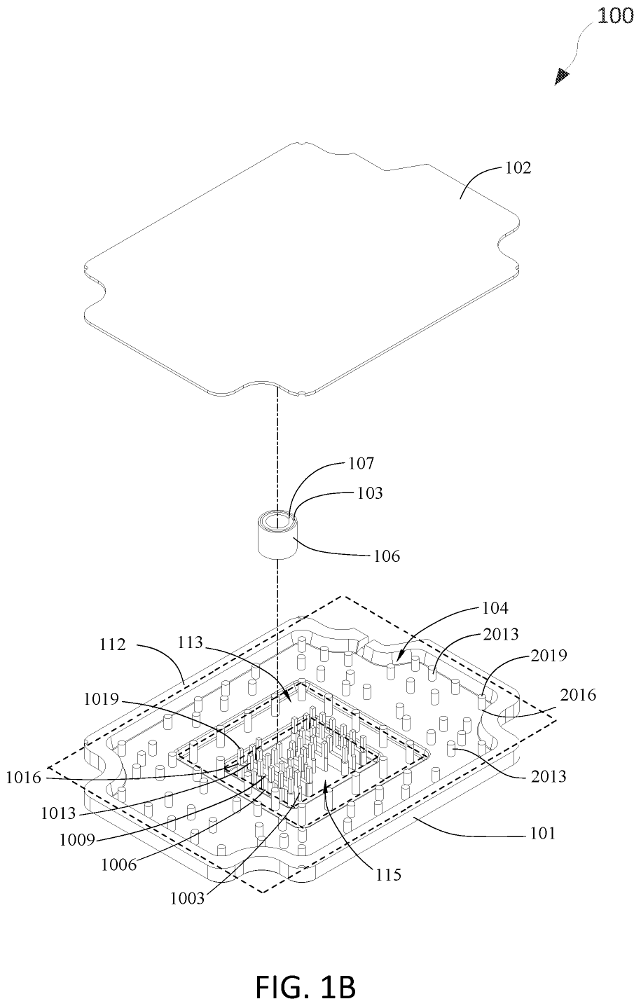

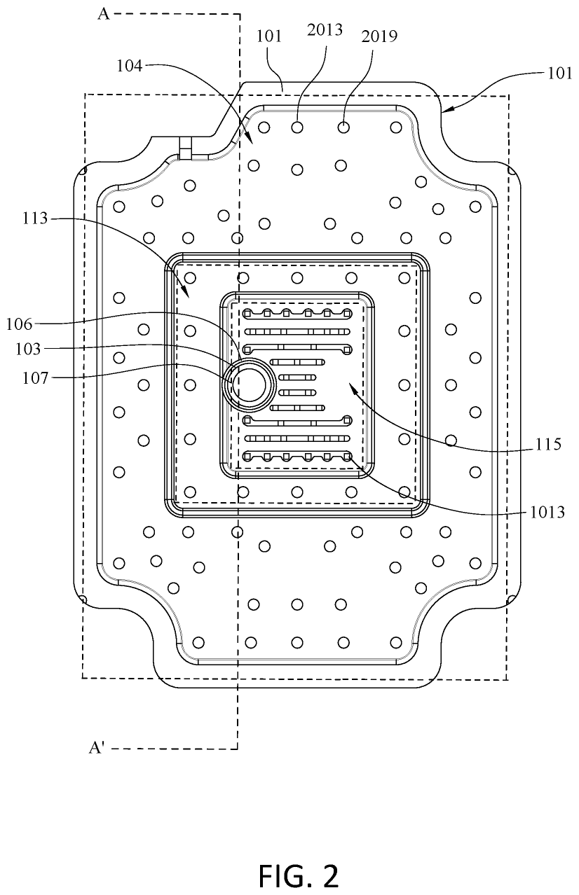

FIGS. 1A, 1B, and 2 show a vapor chamber 100 according to aspects of the present disclosure in different perspective views. The vapor chamber 100 can include a first plate 101, a second plate 102, a plurality of first support structures 1013, a plurality of second support structures 2013, and at least one tubular heat transfer structure 103. The second plate 102 is opposite the first plate 101, and the first plate 101 and the second plate 102 define an interior cavity. The interior cavity includes a first portion 115, a second portion 113, and a third portion 104. The first portion 115 is surrounded by the second portion 113 at a perimeter edge of the first portion 115, and the second portion 113 is surrounded by the third portion 104 at a perimeter edge of the second portion 113. The first portion 115 has a first depth D1 extending from the first plate 101 to the second plate 102, the second portion 113 has a second depth D2 extending from the first plate 101 to the second plate 102, and the third portion 104 has a third depth D3 extending from the first plate 101 to the second plate 102. The first depth D1 is greater than the second depth D2 and the second depth D2 is greater than the third depth D3.

The plurality of first support structures 1013 is disposed in the first portion 115. Each plurality of first support structures 1013 has a first end 1019 and a second end 1016 opposite to each other. The first end 1019 of the first support structures 1013 can contact the second plate 102. The plurality of second support structures 2013 is disposed in the second portion 113 and the third portion 104, respectively. Each plurality of second support structures 2013 has a first end 2019 and a second end 2016 opposite to each other. The first ends 2019 of the second support structures 2013 can contact the second plate 102. The second ends 2016 of the second support structures 2013 can contact the first plate 101. The tubular heat transfer structure 103 is disposed in the first portion 115 and extends from the first plate 101 to the second plate 102. The tubular heat transfer structure 103 can include a first working fluid (not shown). The first working fluid can have a first working fluid circulation path. The first portion 115, the second portion 113, and the third portion 104 can include a second working fluid (not shown). The second working fluid can have a second working fluid circulation path different from the first working fluid circulation path.

In at least one embodiment, each of the second plate 102 and the first plate 101 include a substantially flat perimeter ledge surface 112 and the second plate 102 is bonded to the first plate 101 via each of the substantially flat perimeter ledge surfaces 112 to define the interior cavity. In at least one embodiment, a profile shape of the vapor chambers 100 can be a square-like shape, whereby a profile shape of the first portion 115 can be a square-like shape, a profile shape of the second portion 113 can be a hollow square-like shape, and a profile shape of the third portion 104 can be a hollow square-like shape, and whereby a cross-section shape of the third portion 104 to the second portion 113 to the first portion 115 can be a step shape.

As shown in FIG. 1B, the vapor chamber 100 can includes a plurality of heat transfer base structures 1003. The plurality of heat transfer base structures 1003 is disposed in the first portion 115. Each heat transfer base structure 1003 has a first heat transfer base contact end 1009 and a second heat transfer base contact end 1006 opposite to each other. The second heat transfer base contact ends 1006 can contact the first plate 101. The first heat transfer base contact ends 1009 can contact the second ends 1016 of the first support structures 1013. Each of the plurality of heat transfer base structures 1003 can be disposed spaced apart from each other and parallel to each other.

The plurality of first support structures 1013 can have a cuboid shape. The plurality of second support structures 2013 can have a cylinder shape. The plurality of heat transfer base structures 1003 can have at least one of an elongated oval-like shape, an elongated barbell-like shape, or a wavy bump shape. The tubular heat transfer structure 103 can have a hollow cylinder shape. However, other shapes can also be used to form the first support structure 1013, the second support structure 2013, the heat transfer base structure 1003, and the tubular heat transfer structure 103 according to the desired structure in an embodiment.

In at least one embodiment, a height of the plurality of first support structures 1013, a height of the plurality of heat transfer base structures 1003, and a height of the at least one tubular heat transfer structure 103 are dependent on the first depth D1 of the first portion 115 extending from the first plate 101 to the second plate 102. A height of the plurality of second support structures 2013 is dependent on the second depth D2 of the second portion 113 or the third depth D3 of the third portion 104 extending from the first plate 101 to the second plate 102. For example, the heights of the second support structures 2013 disposed in the second portion 113 are dependent on the second depth D2 of the second portion 113. For example, the heights of the second support structures 2013 disposed in the third portion 104 are dependent on the second depth D3 of the third portion 104.

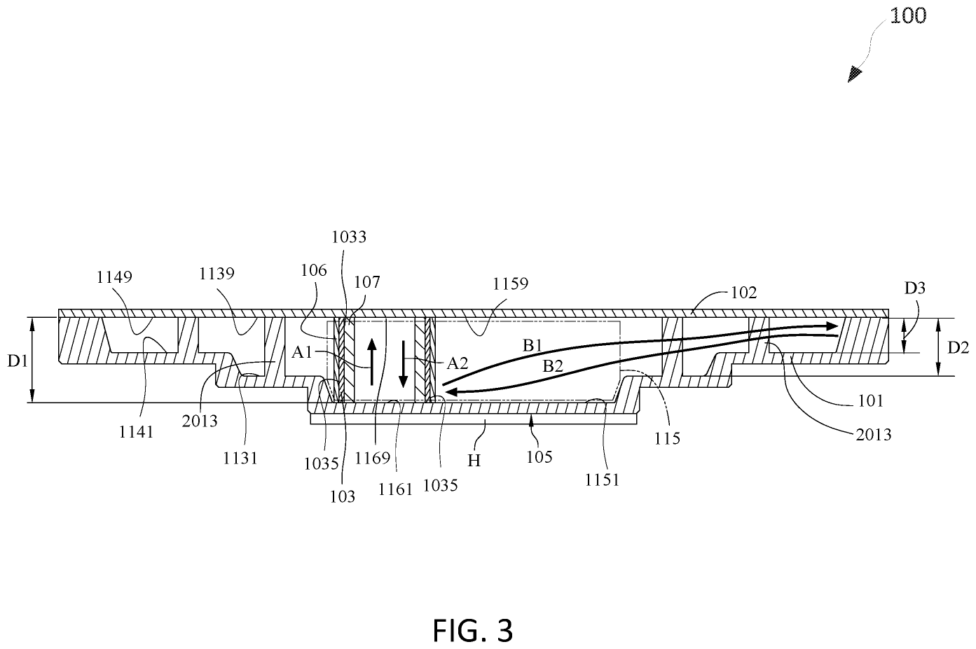

FIG. 3 illustrates working fluid circulation paths A1/A2 and B1/B2 of the vapor chamber 100 at cut line A-A′ as shown in FIG. 2. In at least one embodiment, the interior cavity can include a first surface area 1159 defined by a second plate surface area of the first portion 115, a second surface area 1139 defined by a second plate surface area of the second portion 113, and a third surface area 1149 defined by a second plate surface area of the third portion 104, whereby the first surface area 1159, the second surface area 1139, and the third surface area 1149 are configured so that a gas phase of the second working fluid condenses back into a liquid phase when cooled. The tubular heat transfer structure 103 can include a first working fluid (not shown) having a first working fluid circulation path A1/A2. The first portion 115, the second portion 113, and the third portion 104 can include a second working fluid (not shown). The second working fluid can have a second working fluid circulation path B1/B2 that is different from the first working fluid circulation path A1/A2. The tubular heat transfer structure 103 can have a outer tubular liquid flow surface 1035 and an inner tubular liquid flow surface 1033. The tubular heat transfer structure 103 can further include a first tubular surface area 1161 and a second tubular surface area 1169.

The interior cavity can further include a plurality of first liquid flow surfaces 1151, a plurality of second liquid flow surfaces 1131, and a plurality of third liquid flow surfaces 1141. The plurality of first liquid flow surfaces 1151 is defined by a first plate surface area of the first portion 115 and surface areas of each of the plurality of second support structures 2013 and surface areas of each of the plurality of heat transfer base structures 1003 disposed in the first portion 115. The plurality of second liquid flow surfaces 1131 is defined by a first plate surface area of the second portion 113 and surface areas of each of the plurality of second support structures 2013 disposed in the second portion 113. The plurality of third liquid flow surfaces 1141 is defined by a first plate surface area of the third portion 104 and surface areas of each of the plurality of support structures 2013 disposed in the third portion 104. The plurality of first liquid flow surfaces 1151, the plurality of second liquid flow surfaces 1131, and the plurality of third liquid flow surfaces 1141 are configured so that the second working fluid that is condensed back into a liquid phase when cooled and flows to the outer tubular liquid flow surface 1035 of the at least one tubular heat transfer structure 103.

In at least one embodiment, the vapor chamber 100 can further include an outer tubular capillary structure 106. The outer tubular capillary structure 106 is disposed on the outer tubular liquid flow surface 1035. In at least one embodiment, the second working fluid circulation path B1/B2 can be defined from the outer tubular capillary structure 106 of the at least one tubular heat transfer structure 103, to at least one of the first surface area 1159, the second surface area 1139, and the third surface area 1149, and then back through at least one of the plurality of first liquid flow surfaces 1151, the plurality of second liquid flow surfaces 1131, or the plurality of third liquid flow surfaces 1141, to the outer tubular liquid flow surface 1035.

In at least one embodiment, the first tubular surface area 1161 is further configured so that the first working fluid transitions between a liquid phase and a gas phase when heated. In at least one embodiment, the outer tubular liquid flow surface 1035 is configured so that the second working fluid that is condensed back into a liquid phase when cooled flows to the first liquid flow surfaces 1151. The first tubular surface area 1161 is defined by a first plate surface area of the at least one tubular heat transfer structure 103, and the second tubular surface is defined by a second plate surface area of the at least one tubular heat transfer structure 103. The first tubular surface area 1161 is configured so that the first working fluid transitions between a liquid phase and a gas phase when heated. The second tubular surface area 1169 is configured so that the first working fluid condenses back into a liquid phase when cooled The inner tubular liquid flow surface 1033 is configured so that the first working fluid that is condensed back into a liquid phase when cooled flows to the first tubular surface area 1161. The first working fluid circulation path A1/A2 is defined from the first tubular surface area 1161, to the second tubular surface area 1169, and then back through the inner tubular liquid flow surface 1033, to the first tubular surface area 1161. In at least one embodiment, the vapor chamber 100 can further include an inner tubular capillary structure 107, the inner tubular capillary structure 107 is disposed on the inner tubular liquid flow surface 1033.

In at least one embodiment, the vapor chamber 100 can further include a heat source contact surface 105 opposite the first portion 115. The heat source contact surface 105 is configured to thermally couple to a heat source H (not shown). The at least one tubular heat transfer structure 103 can decrease a vapor space of the first portion 115 The at least one tubular heat transfer structure 103 can increase a temperature within the first portion 115. The at least one tubular heat transfer structure 103 can increase a temperature difference between the temperature within the first portion 115 and the temperature within the second portion 113 and the third portion 104 when the heat source contact surface 105 is thermally coupled to the heat source H. In at least one embodiment, at least two of the plurality of first support structures 1013 is disposed on each of the plurality of heat transfer base structures 1003. In addition to the plurality of first support structures 1013 disposed on each of the plurality of heat transfer base structures 1003 and the plurality of support structures 2013, an allowable compressive force of the vapor chamber 100 to the heat source H before the vapor chamber 100 collapses is increased via the at least one tubular heat transfer structure 106.

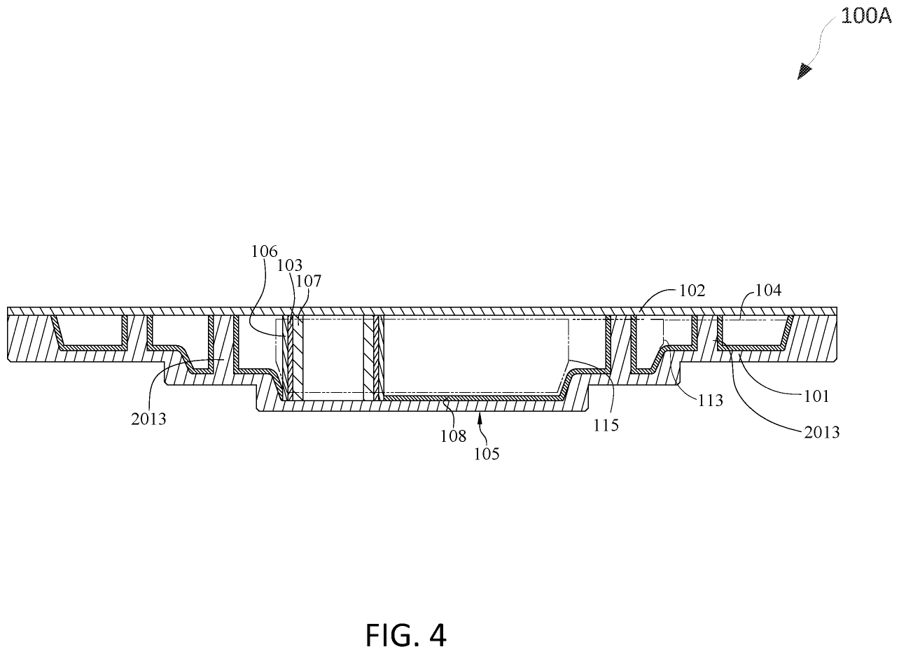

FIG. 4 illustrates an alternative vapor chamber 100A. The vapor chamber 100A of FIG. 4 may be similar in some respects to the vapor chamber 100 of FIGS. 1A, 1B, 2, and 3, and therefore may be best understood with reference thereto where like numerals designate like components not described again in detail. The vapor chamber 100A can include a capillary structure 108. The capillary structure 108 is disposed on the plurality of first liquid flow surfaces 1151, the plurality of second liquid flow surfaces 1131, and the plurality of third liquid flow surfaces 1141.

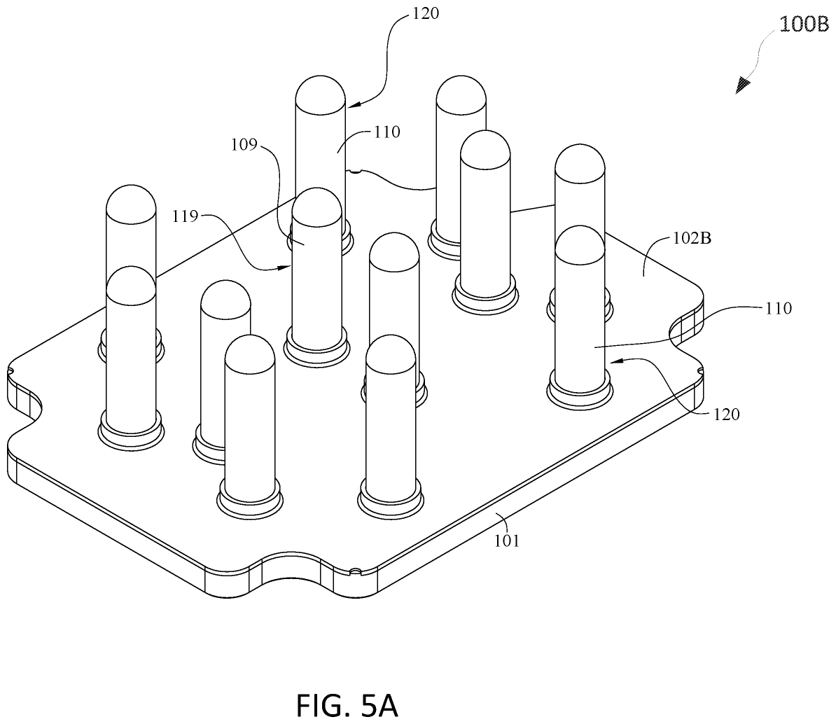

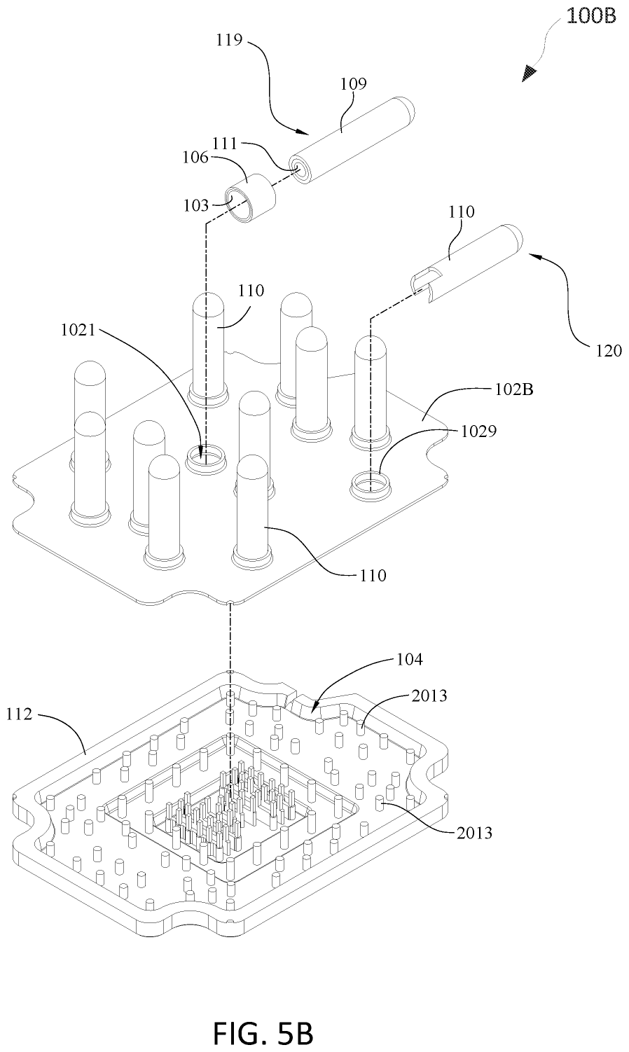

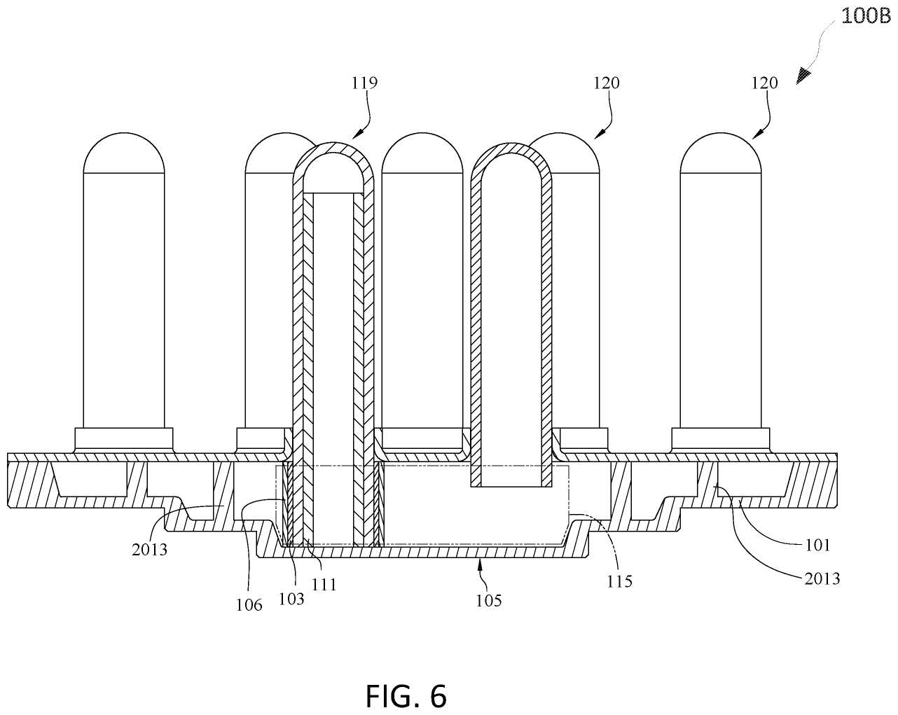

FIGS. 5A, 5B, and 6 illustrate another alternative vapor chamber 100B. The vapor chamber 100B of FIGS. 5A, 5B, and 6 may be similar in some respects to the vapor chamber 100 of FIGS. 1A, 1B, 2, and 3 and the vapor chamber 100A of FIG. 4, and therefore may be best understood with reference thereto where like numerals designate like components not described again in detail. The vapor chamber 100B can further include a first heat pipe 119 having a first pipe body 109 and a pipe capillary structure 111. The second plate 102B can include at least one through hole 1021 and at least one flange 1029. The pipe capillary structure 111 is disposed in the first pipe body 109. Each of the at least one flange 1029 extends from each of the at least one through hole 1021, respectively. The at least one through hole 1021 is disposed through the first surface area 1159. The first heat pipe 119 is received in the at least one through hole 1021 and the at least one tubular heat transfer structure 103. The at least one flange 1029 and the at least one tubular heat transfer structure 103 surround the first heat pipe 119.

The first working fluid circulation path is defined from the first tubular surface area 1131, to an upper portion of the first pipe body 109, and then back through the pipe capillary structure 111, to the first tubular surface area 1131. In at least one embodiment, the vapor chamber 100B can further include a plurality of second heat pipes 120, each, including a second pipe body 110. Each of the plurality of heat pipes 120 is received in the at least one through hole 1021, and the at least one flange 1029 surrounds each of the plurality of second heat pipes 120, respectively. The at least one through hole 1021 is disposed through at least one of the second surface area 1139 and the third surface area 1149. The second working fluid circulation path is defined from the outer tubular capillary structure 106 of the at least one tubular heat transfer structure 103, to at least one of the first surface area 1159, the second surface area 1139 and each of an upper portion of the plurality of second heat pipes 120, and the third surface area 1149 and each of an upper portion of the plurality of second heat pipes 120, and then back through at least one of the plurality of first liquid flow surfaces 1151, the second pipe body 110 and the plurality of second liquid flow surfaces 1131, and second the pipe body 110 and the plurality of third liquid flow surfaces 1141, to the outer tubular liquid flow surface 1035.

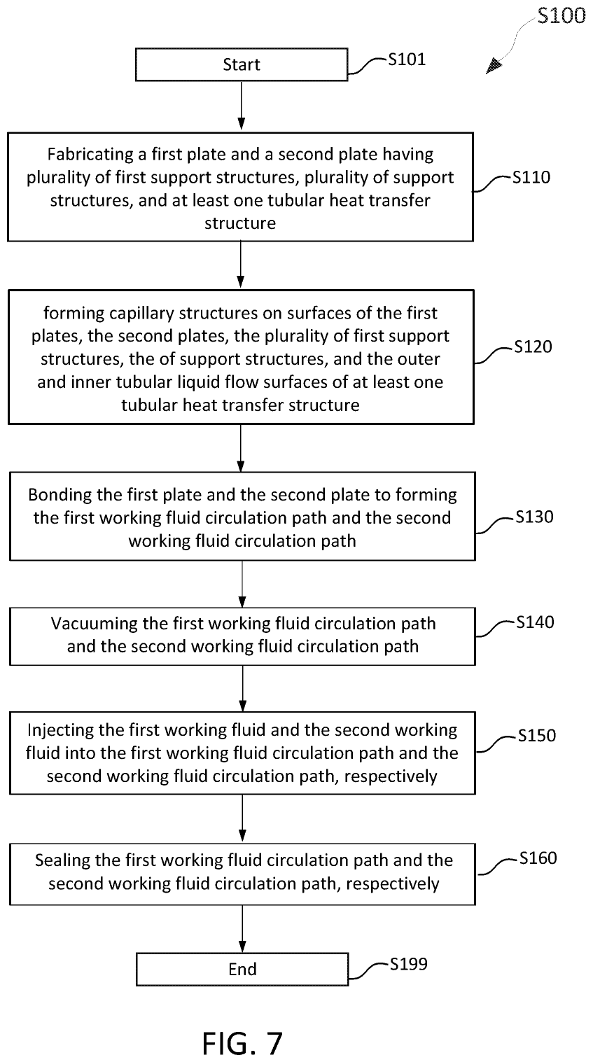

FIG. 7 illustrates a process S100 of manufacturing the vapor chamber 100. The process S100 can start at S101 and proceed to S100.

At S110, a first plate and a second plate having plurality of first support structures, plurality of second support structures and at least one tubular heat transfer structure can be fabricated. In an embodiment, the first plate and the second plate can be forged or machined by CNC process. In an embodiment, the plurality of first support structures, the plurality of second support structures, and the at leat one tubular heat transfer structure can be integrally formed with the first plate. In an embodiment, the plurality of first support structures, the plurality of second support structures, and the at least one tubular heat transfer structure can be integrally formed with the second plate. In an embodiment, the plurality of first support structures, the plurality of second support structures, and the at least one tubular heat transfer structure can be integrally formed with the first plate or the second plate or in any combination with the first and second plate.

At S120, capillary structures can be formed on surfaces of the first plate, the second plate, the plurality of first support structures, the plurality of second support structures, the outer/inner tubular liquid flow surfaces, and the at least one tubular heat transfer structure. In an embodiment, the capillary structure can be formed by sintering metal powder. In an embodiment, the capillary structure can be formed by sintering ceramic. In an embodiment, the capillary structure can be made by a metal wire mesh. In an embodiment, the capillary structure can be made or formed by any combination of the foregoing.

At S130, the first plate and the second plate can be bonded to form a first and a second working fluid circulation paths.

At S140, the first working fluid circulation path and the second working fluid circulation path can be vacuumed.

At S150, the first working fluid and the second working fluid can be injected into the first working fluid circulation path and the second working fluid circulation path respectively.

At S160, the first working fluid circulation path and the second working fluid circulation path can be sealed. The process S100 proceeds to S199 and terminates at S199.

The vapor chambers 100, 100A, 100B of the present disclosure increase surface area, and provide for at least two separate working fluid circulation paths A1/A2 and B1/B2, efficiently distributing heat along the vapor chambers 100, 100A, 100B. The effectiveness of the vapor chambers 100, 100A, and 100B to dissipate heat via the phase change (liquid-vapor-liquid) mechanism is improved, increasing the thermal performance of the vapor chambers 100, 100A, 100B. The at least one tubular heat transfer structure 103 disposed in the first portion 115 decreases a vapor space of the first portion 115, increasing a temperature within the first portion 115, and increasing a temperature difference between the temperature within the first portion 115 and the temperature within the second portion 113 and between the temperature within the first portion 115 and the temperature within the third portion 104. Thus, heat along the third portion 104 is more effectively distributed and a velocity of flow of working fluid condensed back into a liquid phase from the third portion 104 and the second portion 113 to the outer tubular liquid flow surface 1035 (second working fluid circulation path B1/B2) is increased. Furthermore, a surface area is increased and the first working fluid circulation path A1/A2 of the at least one tubular heat transfer structure 103 provides for a separate working fluid circulation path. The additional separate working fluid circulation path increases thermal performance of the vapor chamber 100, 100A, and 100B directly opposite from the heat source H. Yet furthermore, the heat transfer base structures disposed in the first portion 115 also decrease the vapor space of the first portion 115, while concurrently transporting heat directly opposite from the heat source H to the second surface area 1139 via the first support structures 1013 and the plurality of heat transfer base structures 1003, further improving thermal performance of the vapor chambers 100, 100A, 100B. Additionally, the first heat pipe 119 and the plurality of heat pipes 120 further increases surface area within the first portion 115 and the second and third portions 113, 104, respectively, even further improving thermal performance of the vapor chambers 100, 100A, and 100B.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

What is claimed is:

1. A vapor chamber, comprising:
a first plate,
a second plate opposite the first plate, the first plate and the second plate defining an interior cavity, the interior cavity comprising, a first portion, a second portion, and a third portion, the first portion surrounded by the second portion at a perimeter edge of the first portion, the second portion surrounded by the third portion at a perimeter edge of the second portion, the first portion having a first depth extending from the first plate to the second plate, the second portion having a second depth extending from the first plate to the second plate, and the third portion having a third depth extending from the first plate to the second plate;
a plurality of first support structures disposed in the first portion, each plurality of first support structures having a first ends and a second end opposite to each other, he first ends of the first support structures contact the second plate;
a plurality of support structures disposed in the second portion and the third portion, respectively, each plurality of support structures having a end and a second end opposite to each other, the first ends of the second support structure contact the second plate, and the second ends of the second support structures contact the first plate; and
at least one tubular heat transfer structure disposed in the first portion, the at least one tubular heat transfer structure extending from the first plate to the second plate and including a first working fluid having a first working fluid circulation path;
wherein the first depth is greater than the second depth and the second depth is greater than the third depth, and
wherein the first portion, the second portion, and the third portion include a second working fluid having a second working fluid circulation path different from the first working fluid circulation path.

2. The vapor chamber of claim 1, further comprising a plurality of heat transfer base structures, the plurality of heat transfer base structures disposed in the first portion, each plurality of heat transfer base structures having a first heat transfer base contact end and a second heat transfer base contact end opposite to each other, the second heat transfer base contact ends contact the first plate, the first heat transfer base contact ends contact the first ends of the first support structures.

3. The vapor chamber of claim 2, wherein the interior cavity further includes:
a first surface area defined by a second plate surface area of the first portion,
a second surface area defined by a second plate surface area of the second portion, and
a third surface area defined by a second plate surface area of the third portion,
wherein the first surface area, the second surface area, and the third surface area are configured so that a gas phase of the second working fluid condenses back into a liquid phase when cooled.

4. The vapor chamber of claim 3, wherein the interior cavity further includes:
a plurality of first liquid flow surfaces defined by a first plate surface area of the first portion and surface areas of each of the plurality of support structures and surface areas of each of the plurality of heat transfer base structures disposed in the first portion;
a plurality of second liquid flow surfaces defined by a first plate surface area of the second portion and surface areas of each of the plurality of support structures disposed in the second portion; and
a plurality of third liquid flow surfaces defined by a first plate surface area of the third portion and surface areas of each of the plurality of support structures disposed in the third portion;
wherein the plurality of first liquid flow surfaces, the plurality of second liquid flow surfaces, and the plurality of third liquid flow surfaces are configured so that the second working fluid that is condensed back into a liquid phase when cooled flows to an outer tubular liquid flow surface of the at least one tubular heat transfer structure.

5. The vapor chamber of claim 4, further comprising a capillary structure, the capillary structure is disposed on the plurality of first liquid flow surfaces, the plurality of second liquid flow surfaces, and the plurality of third liquid flow surfaces.

6. The vapor chamber of claim 4, further comprising an outer tubular capillary structure, the outer tubular capillary structure is disposed on the outer tubular liquid flow surface.

7. The vapor chamber of claim 4, wherein the first plate surface area is further configured so that the first working fluid transitions between a liquid phase and a gas phase when heated.

8. The vapor chamber of claim 4, wherein the second working fluid circulation path is defined from the outer tubular liquid flow surface of the at least one tubular heat transfer structure, to at least one of the first surface area, the second surface area, and the third surface area, and then back through at least one of the plurality of first liquid flow surfaces, the plurality of second liquid flow surfaces, or the plurality of third liquid flow surfaces, to the outer tubular liquid flow surface.

9. The vapor chamber of claim 4, wherein the outer tubular liquid flow surface is configured so that the second working fluid that is condensed back into a liquid phase when cooled flows to the first plate surface area, and wherein the at least one tubular heat transfer structure further includes a first tubular surface area, a second tubular surface area, and an inner tubular liquid flow surface, the first tubular surface area defined by a first plate surface area of the at least one tubular heat transfer structure, and the second tubular surface defined by a second plate surface area of the at least one tubular heat transfer structure, wherein the first tubular surface area is configured so that the first working fluid transitions between a liquid phase and a gas phase when heated, the second tubular surface area is configured so that the first working fluid condenses back into a liquid phase when cooled, and the inner tubular liquid flow surface is configured so that the first working fluid that is condensed back into a liquid phase when cooled flows to the first tubular surface area, and wherein the first working fluid circulation path is defined from the first tubular surface area, to the second tubular surface area, and then back through the inner tubular liquid flow surface, to the first tubular surface area.

10. The vapor chamber of claim 9, further comprising an inner tubular capillary structure, the inner tubular capillary structure is disposed on the inner tubular liquid flow surface.

11. The vapor chamber of claim 1, wherein a shape of the plurality of first support structures comprise a cuboid shape, and wherein a shape of the plurality of support structures comprise a cylinder shape.

12. The vapor chamber of claim 2, wherein a shape of the plurality of heat transfer base structures comprise at least one of an elongated oval-like shape, an elongated barbell-like shape, or a wavy bump shape.

13. The vapor chamber of claim 1, further comprising a heat source contact surface opposite the first portion, the heat source contact surface configured to thermally couple to a heat source, whereby the at least one tubular heat transfer structure decreases a vapor space of the first portion, increasing a temperature within the first portion, and increasing a temperature difference between the temperature within the first portion and the temperature within the second portion and the third portion when the heat source contact surface is thermally coupled to the heat source.

14. The vapor chamber of claim 2, wherein at least two of the plurality of first support structures is disposed on each of the plurality of heat transfer base structures.

15. The vapor chamber of claim 9, further comprising a first heat pipe having a first pipe body and a pipe capillary structure, the pipe capillary structure disposed in the first pipe body, and wherein the second plate includes at least one through hole and at least one flange, each of the at least one flange extending from each of the at least one through hole, respectively, wherein the at least one through hole is disposed through the first surface area, and whereby the first heat pipe is received in the at least one through hole and the at least one tubular heat transfer structure, and the at least one flange and the at least one tubular heat transfer structure surround the first heat pipe, and wherein the first working fluid circulation path is defined from the first tubular surface area, to an upper portion of the first pipe body, and then back through the pipe capillary structure, to the first tubular surface area.

16. The vapor chamber of claim 15, further comprising a plurality of heat pipes, each, including a pipe body, wherein, each of the plurality of heat pipes is received in the at least one through hole, and the at least one flange surrounds each of the plurality of heat pipes, respectively, and wherein the at least one through hole is disposed through at least one of the second surface area and the third surface area, wherein the second working fluid circulation path is defined from the outer tubular capillary structure of the at least one tubular heat transfer structure, to at least one of the first surface area, the second surface area and each of an upper portion of the plurality of heat pipes, and the third surface area and each of an upper portion of the plurality of heat pipes, and then back through at least one of the plurality of first liquid flow surfaces, the pipe body and the plurality of second liquid flow surfaces, and the pipe body and the plurality of third liquid flow surfaces, to the outer tubular liquid flow surface.
